(19) United States
(12) Patent Application Publication
(10) Pub. No.: US 2026/0312313 A1
(43) Pub. Date: Oct. 8, 2026

(54) Electrical Assembly and Method for Installing an Electrical Assembly

(71) Applicants: ROSENBERGER HOCHFREQUENZTECHNIK GMBH & CO. KG, Fridolfing (DE); ENDRESS+HAUSER SE+Co. KG, Maulburg (DE)

(72) Inventors: Markus Schichl, Seekirchen (AT); Simon Huber, Engelsberg (DE); Markus Margardt, Altoetting (DE); Simon Gerwig, Schopfheim (DE); Hans-Joerg Brock, Grenzach-Wyhlen (DE); Christian Strittmatter, Rickenbach (DE); Raphael Schonhardt, Rheinfelden (DE)

(21) Appl. No.: 19/634,307

(22) Filed: Mar. 31, 2026

(30) Foreign Application Priority Data
Apr. 2, 2025 (EP) 25167932.0

(51) Int. Cl. H01R 12/72; H01R 12/70; H01R 13/14; H01R 13/6595

(52) U.S. Cl. CPC H01R 12/727; H01R 12/7064; H01R 13/14; H01R 13/6595

(57) ABSTRACT

An electrical assembly, having an assembly housing, at least one electrical circuit arrangement received in the assembly housing and an electrical connector, which has a connecting interface that is electrically and mechanically connected to a corresponding connection region of the electrical circuit arrangement. The electrical connector passes through an installation feedthrough of the assembly housing. Provision is made for the connecting interface of the electrical connector and the connection region of the electrical circuit arrangement to make contact in a force-fitting manner.

### FIELD OF THE INVENTION

The invention relates to an electrical assembly, having an assembly housing, at least one electrical circuit arrangement received in the assembly housing and an electrical connector.

The invention also relates to a method for installing an electrical assembly.

An electrical assembly is generally a collection of electrical or electronic components. An electrical assembly is often integrated into relatively large systems, such as household appliances, computers, vehicles, or industrial machinery, to perform specific tasks. Typical examples of electrical assemblies are power supply units, control modules, communication modules and sensor modules. An electrical assembly generally comprises a circuit arrangement consisting of electrical components, such as, inter alia, resistors, capacitors, coils, diodes, transistors and integrated circuits (ICs), which are usually arranged on one or more common carrier plates, in particular on electrical printed circuit boards (PCBs). Electrical assemblies often comprise an assembly housing in order to fix the electronic components in a defined arrangement and to electrically and/or mechanically protect them from external influences.

In practice, it is often the case that power is supplied to, and electrical data signals are exchanged with, the electrical assembly via electrical connectors that are passed through the assembly housing and must be connected to the electrical circuit within the assembly housing. Printed circuit board plug-in connectors are often used to make an electrical circuit arranged on a printed circuit board electrically accessible from outside the assembly housing. For this purpose, the printed circuit board plug-in connectors are soldered onto corresponding contact surfaces and/or into vias of the printed circuit board.

In practice, installing the electrical connectors on the printed circuit board often proves to be time-consuming. This is because electrical assemblies and their assembly housings are sometimes designed to be compact in order to save on space and reduce costs. This hinders the access to the electrical circuits, and therefore the installability of the electrical connectors. In particular, it is usually problematic to first solder the electrical connectors to the electrical printed circuit board and then to pass them through the assembly housing as well. In practice, the assembly housings must therefore generally either be designed to be oversized in an unfavorable way or alternatively be of multi-part design. In the case of a multi-part assembly housing, in particular at a connection point of the housing parts in the region of the installation feedthrough of the electrical connector, there is then the risk that sealing requirements, electromagnetic shielding that may be required and/or mechanical load requirements may no longer be sufficiently ensured.

This is a condition that needs to be improved.

In view of the known prior art, the object of the present invention consists in providing an electrical assembly that is simple and inexpensive to install, with a design that is preferably compact and robust.

The present invention is also based on the object of providing a method, which is able to be carried out in a simple and inexpensive manner, for installing an electrical assembly, preferably for an electrical assembly with a compact and robust design.

The object is achieved, for the electrical assembly, by means of the features disclosed herein. With regard to the method, the object is achieved by means of the features disclosed herein.

### SUMMARY OF THE INVENTION

The features described below relate to advantageous embodiments and variants of the invention.

An electrical assembly is provided, having an assembly housing, at least one electrical circuit arrangement received in the assembly housing and at least one electrical connector.

The electrical connector has at least one connecting interface that is electrically and mechanically connected to a corresponding connection region of the electrical circuit arrangement.

In principle, the electrical assembly may have any desired number of electrical circuit arrangements, for example precisely one, two, three, four, five, six or more electrical circuit arrangements. The invention is described below with reference to an electrical assembly that has precisely one electrical circuit arrangement, which, however, is not intended to be understood as limiting.

The electrical assembly may have precisely one electrical connector, but also a plurality of electrical connectors, for example two, three, four, five, six or more electrical connectors.

The electrical connectors may be distributed between a plurality of electrical circuit arrangements, wherein, however, provision may also be made for a single electrical circuit arrangement to be connected to a plurality of electrical connectors. The invention is described below by way of example with reference to an electrical assembly that only has a single electrical connector, which, however, is not intended to be understood as limiting.

In particular, it should be emphasized that provision may also be made for an electrical connector to be electrically and mechanically connected to a plurality of electrical circuit arrangements. The electrical connector may then have a respective connecting interface for each circuit arrangement or a common connecting interface for a plurality of circuit arrangements. The electrical circuit arrangements to which the common electrical connector is connected are preferably arranged in parallel with one another for this purpose. However, an angular arrangement up to an orthogonal arrangement of the electrical circuit arrangements may also be possible in principle.

According to the invention, provision is made for the electrical connector to be passed through an installation feedthrough of the assembly housing.

One end of the electrical connector (referred to as “connection-side end” below) may be used to further connect the electrical connector to a further electrical assembly or other electrical apparatus in order to exchange electrical data and/or supply signals. For this purpose, it is advantageous to make the connection-side end of the electrical connector accessible from outside the assembly housing, for example to guide it outwards. In particular, provision may be made for the connection-side end of the electrical connector to be arranged within the installation feedthrough or at least partially outside the assembly housing in the installed state of the electrical connector in which the electrical connector is electrically and mechanically connected to the electrical circuit arrangement.

The connection-side end of the electrical connector may preferably have a connecting interface, for example a plug-in interface, for connection to a corresponding mating connector (the electrical connector may therefore preferably be an electrical plug-in connector and the electrical mating connector an electrical mating plug-in connector). However, provision may also be made for the connection-side end of the electrical connector to have a cable feed or a cable outlet and therefore to be directly connected to an electrical cable. In addition, provision may be made for the connection-side end of the electrical connector to be directly connected to a further electrical circuit arrangement, for example, to an electrical circuit on an electrical printed circuit board. In principle, the electrical connector may provide any desired electrical connection option at the connection-side end (in special cases, even a wireless connection option by means of an antenna arrangement).

In particular, if the connection-side end of the electrical connector does not protrude outwards from the installation feedthrough of the assembly housing, provision may be made for the installation feedthrough to be optionally closable (for example by means of a cover element) to prevent an ingress of moisture or contamination when the electrical connector is not being used.

According to the invention, provision is made for the connecting interface of the electrical connector and the connection region of the electrical circuit arrangement to make contact in a force-fitting manner.

The fact that the connecting interface of the electrical connector and the connection region of the electrical circuit arrangement make contact in a force-fitting manner may ensure that the electrical connector is able to be installed in a technically simple manner. In particular, a soldering process, which is often required in the context of installing an electrical assembly, for connecting the electrical connector to the electrical circuit arrangement is able to omitted, which allows the electrical connector to be able to installed even in the case of confined installation space and poor accessibility (for example also a “blind” installation or installation with poor visibility).

There is preferably no cohesive contacting between the connection region of the electrical circuit arrangement and the connecting interface of the electrical connector. In particular, there is preferably no soldered connection and/or welded connection between the connecting interface and the connection region.

Optionally, in addition to the force-fitting contacting between the connecting interface and the connection region, there may also be a form-fitting connection, either by way of the connecting interface and the connection region themselves or by way of additional measures or means of connecting the electrical connector and the electrical circuit arrangement, such as latching and snap-action hooks, for example.

Preferably, the connecting interface of the electrical connector and the connection region of the electrical circuit arrangement make contact in such a way that the connection is able to be non-destructively released as required. There is preferably no permanent, inseparable connection between the electrical connector and the electrical circuit arrangement.

In one advantageous development of the invention, provision may be made for the connecting interface of the electrical connector and the connection region of the electrical circuit arrangement to make contact laterally.

The specification “laterally” thus relates in particular to a longitudinal direction of extent of the electrical connector along a longitudinal axis and/or to an installation direction of the electrical connector.

The contacting direction or a force vector of the contacting of contact elements of the connecting interface and corresponding contact elements of the connection region thus preferably runs at an angle, preferably orthogonally or at least substantially orthogonally, to the longitudinal axis of the electrical connector or to the installation direction thereof. The electrical connector may therefore be pushed onto the electrical circuit arrangement longitudinally during installation, or slide along the electrical assembly laterally during installation, until the final installed state is reached.

However, in principle, provision may also be made for the connecting interface of the electrical connector and the connection region of the electrical circuit arrangement (or the contact elements thereof) to make contact at the end faces thereof. Therefore, provision may also be made for end-face contact to be made between the electrical connector and the electrical printed circuit board (alternatively or in addition to the lateral contacting). In the context of the fundamental idea of the invention, the end-face contacting may also be carried out in a force-fitting manner, preferably only in a force-fitting manner.

According to one development of the invention, provision may be made for the connection region of the electrical circuit arrangement to be received at least partially in the connecting interface.

In the region of the connecting interface, the electrical connector may advantageously be plugged onto the electrical circuit arrangement or the electrical circuit arrangement may be partially plugged into the electrical connector. The electrical connector may have a receptacle suitable for this purpose.

The electrical connector particularly preferably has a receiving slot for the electrical circuit arrangement, preferably at least in the region of the connecting interface, in which the connection region of the circuit arrangement may be inserted. This configuration has proven to be particularly suitable if the electrical circuit arrangement has an electrical circuit that is arranged on an electrical carrier plate, such as an electrical printed circuit board, since the carrier plate or the electrical printed circuit board is able to be inserted in this case with one side into the receiving slot of the electrical connector.

However, the receptacle for the circuit arrangement does not necessarily have to be in the form of a receiving slot. A bore or the like may also possibly be suitable for partially receiving the electrical circuit arrangement. By way of example, the electrical connector may be partially in the form of a sleeve in the region of the connecting interface.

According to one development of the invention, provision may be made for the connection region of the electrical circuit arrangement to be distributed over two opposite main surfaces of the electrical circuit arrangement, contact being made with each of said main surfaces by the connecting interface.

Two-sided contacting enables a high contact density and is also advantageously suitable for use with an electrical circuit arranged on a carrier plate, such as an electrical printed circuit board, since in this case there is often a two-sided contacting option. However, in principle, provision may also be made for only one-sided contacting between the electrical connector and the electrical circuit arrangement.

In one configuration of the invention, provision may be made for the connecting interface to have at least one contact element, which is preferably of spring-loaded design, for connection to the connection region. The (spring-loaded) contact element may be designed to make contact with a corresponding contact element of the connection region, in particular a contact point of the connection region. Alternatively or in addition, provision may also be made for the connection region to have a spring-loaded contact element. In particular, one of the connecting partners or both connecting partners may have spring-loaded contact elements or contact elements that are at least partially elastic.

In principle, the contact element of the connecting interface or of the connection region may have any desired design. However, spring contact pins or contact spring tabs connected on one or both sides are particularly preferably provided (at least for one of the two connecting partners).

In one particularly preferred development of the invention, provision may be made for the connecting interface to have at least one contact spring tab for connection to the connection region, which contact spring tab makes contact with an associated contact point of the connection region.

The contact point of the connection region may preferably be an electrical conductor track or a contact surface (contact pad) of an electrical printed circuit board or other carrier plate of the electrical circuit arrangement.

In particular, the combination of contact spring tabs of the electrical connector, on the one hand, and contact points of the connection region, on the other hand, has proven to be particularly suitable for connecting the electrical connector to the electrical circuit arrangement in a simple manner during installation.

In one development of the invention, provision may be made for the assembly housing to be a single-piece component.

The assembly housing may preferably be a sleeve-shaped component or a component that is open at one or both sides. Preferably, an outer casing of the assembly housing is at least substantially completely closed (in particular apart from the installation feedthrough or feedthroughs or other smaller openings, such as ventilation slots, viewing openings, etc.). Said outer casing of the assembly housing may have a number of side surfaces that corresponds to the geometry of the assembly housing, for example a single circumferential side surface (in the case of an assembly housing with a round or elliptical cross section) or four side surfaces (in the case of a rectangular cross section). In principle, the outer casing of the assembly housing may have any desired cross section and any desired number of (contiguous) side surfaces.

The assembly housing may be completely closable by one or by two cover elements. The cover element may optionally be intended to be opened by a user during operation of the electrical assembly, or may permanently close the assembly housing after installation. By way of example, the cover element may also be an electronic component, such as an electrical display and/or input device. For example, the cover element may be an electrical display.

Provision may be made for the assembly housing to be an electrically conductive component, in particular a metallic component.

This may advantageously provide electromagnetic shielding of the electrical circuit arrangement. Depending on the application, however, the assembly housing may in principle also be an electrically insulating component, i.e. a plastic housing, for example.

In one advantageous development of the invention, provision may be made for the installation feedthrough to be formed in a closed side surface of the assembly housing. The installation feedthrough is preferably formed in the manner of a window.

The installation feedthrough is therefore preferably not provided at a connecting point between two housing components of a multi-part assembly housing. The electromagnetic shielding, sealing and mechanical robustness of the electrical assembly may therefore be improved.

The installation feedthrough may have any desired geometry. By way of example, the installation feedthrough may have an at least substantially round or rectangular design. In principle, any desired polygonal cross section may be provided.

The installation feedthrough may in particular also be designed to form a twist prevention means for the installed electrical connector and/or to specify a defined installation orientation.

The installation feedthrough may optionally have one or more steps or cross-sectional tapering. However, the profile of the installation feedthrough through the assembly housing may also be smooth.

In one development of the invention, provision may be made for the electrical connector to be fixed to the assembly housing.

The electrical connector may be fixed to the assembly housing in any desired way, in particular (preferably) in a cohesive manner, for example by welding, soldering or adhesively bonding the electrical connector to the assembly housing (in particular the outer conductor contact element, which is mentioned below, of the electrical connector) and/or in a form-fitting manner (for example by means of latching elements, such as latching hooks) and/or in a force-fitting manner (for example by press-fitting the electrical connector into the installation feedthrough). Provision may also be made, in principle, to screw the electrical connector into the installation feedthrough, for example if the installation feedthrough has an internal thread and the electrical connector, for example an outer conductor contact element of the electrical connector, has a corresponding external thread. Alternatively, provision may also be made for only the electrical connector to have an external thread, wherein fixing to the assembly housing is carried out by means of union nuts arranged on the inside and/or outside of the installation feedthrough.

Provision is preferably made for the electrical connector to be fixed to the assembly housing in manner to prevent twisting, with the result that transverse forces and torques acting on the connection-side end of the electrical connector are advantageously dissipated via the assembly housing, and the electrical circuit arrangement or the connection of the electrical connector to the circuit arrangement is not damaged.

In one advantageous development of the invention, provision may be made for the electrical connector and the installation feedthrough of the assembly housing to be designed in such a way that the electrical connector is able to be inserted, by way of a connecting-interface-side end, into the installation feedthrough until it reaches a final installed state in which the connecting interface is connected to the electrical circuit arrangement, from outside the assembly housing.

This advantageously therefore makes it possible to insert the electrical connector into the assembly housing, until it makes contact with the electrical circuit arrangement in the final installed state, completely from outside the assembly housing. The electrical circuit arrangement may therefore already be preinstalled in the assembly housing, which allows a particularly compact design of the assembly housing. The assembly housing may optionally also be already completely closed in this preinstalled state.

The installation feedthrough may advantageously provide a guide for the installation movement of the electrical connector, which further simplifies the installation for an installer and may prevent installation errors and damage to the electrical circuit arrangement during installation.

In one advantageous development of the invention, provision may be made for the electrical connector and the electrical circuit arrangement to form a mutual mechanical coding in order to specify a defined mutual orientation and/or to form a twist prevention means.

By way of example, the electrical connector may have one or more mechanical coding means in the connecting interface, or else optionally outside the connecting interface. The mechanical coding means may preferably be a protrusion, such as a coding bar, a coding pin or a coding rib. However, the specific configuration of the coding means is not limiting for the invention. The electrical circuit arrangement, in particular a carrier plate or an electrical printed circuit board on which the electrical circuit is arranged, may preferably have a mechanical mating coding means, in particular (but not exclusively) a recess or a cutout, such as a longitudinal slot extending in the installation direction of the electrical connector, for example.

Insofar as the mechanical coding means and the mechanical mating coding means are arranged in an off-centered manner, a defined mutual orientation may first be specified and a twist prevention means may also be provided or improved.

A twist prevention means may also already be provided by way of a form-fitting connection between the electrical connector and the electrical circuit arrangement. In particular, the electrical connector may be pushed onto the circuit arrangement laterally with an accurate fit (the circuit arrangement may be received, for example, in the receiving slot, which has already been mentioned, of the electrical connector), wherein a respective bearing surface of the electrical connector (for example of the contact element carrier mentioned below) makes contact directly with a corresponding mating surface of the electrical circuit arrangement, in particular the main surfaces of a carrier plate or electrical printed circuit board. In this way, installing the electrical connector laterally on the electrical circuit arrangement already prevents twisting, with the result that no further measures are required.

Provision may preferably be made for an axial end stop for the installation of the electrical connector on the circuit arrangement. The end stop may in particular be formed between the electrical connector and the assembly housing and/or between the electrical connector and the circuit arrangement. By way of example, an end stop may already be formed by a flange portion of the connection-side end of the electrical connector and/or by the length of the receiving slot mentioned above.

In one advantageous development of the invention, provision may be made for the electrical connector to have an outer conductor contact element.

The outer conductor contact element may in particular be a sleeve-shaped outer conductor contact element that at least substantially envelops the further components of the electrical connector. The outer conductor contact element may preferably be the outer housing of the electrical connector at the same time.

The outer conductor contact element of the electrical connector may preferably be directly connected to the installation feedthrough or make contact directly with the installation feed-through on the inside thereof.

In particular, the mechanical fixing between the installation feedthrough and the electrical connector may be carried out via the outer conductor contact element.

The outer conductor contact element may have a flange portion with which it is able to support itself on the outside of the assembly housing. Insofar as the installation feedthrough is of stepped design, the outer conductor contact element may be accordingly configured in a complementary manner in order to be able to be preferably installed in the installation feedthrough with an accurate fit.

In one development of the invention, provision may be made for the electrical connector to have a contact element carrier, in particular an electrically insulating contact element carrier, for example composed of a plastic.

The contact element carrier may have one or more contact receptacles for receiving and/or fixing electrical contact elements of the electrical connector. The contact receptacles may in particular be respective contact chambers or grooves for a respective contact element. The contact element carrier is preferably received and fixed in the outer conductor contact element mentioned above. For this purpose, a force-fitting and/or form-fitting connection may be provided between the contact element carrier and the outer conductor contact element, which optionally furthermore ensures twist prevention between the outer conductor contact element and the contact element carrier. By way of example, the contact element carrier may have, on its outer casing surface, an installation pin that is received in a corresponding installation receptacle of the outer conductor contact element, or vice versa.

The contact element carrier may preferably be designed to protect the contact elements of the electrical connector, in particular in the region of the connecting interface, from mechanical damage. The contact elements of the electrical connector may therefore preferably be arranged completely within the contact element carrier, in particular in the region of the connecting interface, and, for example, be (laterally) accessible only through the receiving slot, which is mentioned above, for making contact with the circuit arrangement.

In one development of the invention, provision may be made for the electrical connector to have a shielding element that is electrically and mechanically connected to the outer conductor contact element, on the one hand, and to the electrical circuit arrangement, on the other hand. The shielding element is therefore preferably arranged between the outer conductor contact element and the contact element carrier.

Preferably, the shielding element envelops the contact element carrier at least partially, preferably in a sleeve-shaped manner.

The outer conductor attachment of the electrical connector to an outer conductor of the electrical circuit arrangement may therefore be effected via the separate shielding element. In principle, however, the outer conductor attachment may also be effected directly by connecting the outer conductor contact element of the electrical connector to the electrical circuit arrangement.

The shielding element is preferably a punched and bent part.

The shielding element may have at least one first electrical contact tab, preferably a group of a plurality of first electrical contact tabs, which are connected to the outer conductor contact element in a force-fitting manner, and/or at least one second electrical contact tab, preferably a group of a plurality of second electrical contact tabs, which are connected to the electrical circuit arrangement in a force-fitting manner, in particular to corresponding contact points of the electrical circuit arrangement, in particular in the connection region. However, the first and/or the second contact tabs or one or both of the groups of contact tabs mentioned may also, in principle, be omitted if the connection to the outer conductor contact element and/or circuit arrangement is effected in a different way, for example the components being directly pressed together.

According to one preferred variant, contact may be made between the shielding element and the electrical assembly by way of one or more contact clamps, which are arranged laterally in the extension of the receiving slot (preferably on both sides of the receiving slot). A contact clamp may be formed in particular from two opposite second contact tabs.

According to one development of the invention, provision may be made for the electrical circuit arrangement to have a carrier plate, in particular an electrical printed circuit board, and an electrical circuit formed on the carrier plate.

As already mentioned, the invention is particularly advantageously suitable for use with an electrical circuit arrangement having an electrical printed circuit board, since the electrical connector may then advantageously be pushed onto the printed circuit board from the side, in particular if the electrical connector has a suitable receiving slot for the electrical printed circuit board.

In one advantageous development of the invention, provision may be made for the at least one contact element of the electrical connector to extend along a longitudinal extent of the electrical connector up to the connecting interface and to make contact directly with the electrical circuit arrangement in the connection region.

The at least one contact element is preferably formed as a single piece, for example as a punched and bent part.

The electrical contact element may be formed at the connection-side end of the electrical connector for further connecting to, for example, electrical conductors of an electrical cable, for making contact directly with a connection region of a further electrical circuit arrangement or for making contact with corresponding mating contact elements of a mating plug-in connector.

In principle, the invention is suitable for use with an electrical connector with any desired number of electrical contact elements. By way of example, the electrical connector may have precisely one electrical contact element, two, three, four, five, six, seven, eight or more electrical contact elements.

In the context of the invention, all signaling and/or current supply connections are possible in principle. By way of example, the electrical connector may be provided for transmission of an asymmetrical signal, a symmetrical signal, for shielded or unshielded transmission, for DC transmission, for single-phase or multi-phase AC transmission, etc. The electrical connector may advantageously be suitable for supplying any desired current and/or data signals (for example for sensor signal processing) to the electrical assembly and/or to discharge them from the electrical assembly.

The electrical connector is, in principle, suitable for any desired applications within the entire field of electrical engineering and may therefore, in principle, have any desired design. In particular, any connection interface in the region of the connection-side end of the electrical connector may, however, be in the form of a plug-in interface for connection to a corresponding mating plug-in connector.

The connection interface or the connection-side end of the electrical connector may preferably be of at least substantially round design. By way of example, this may therefore be a circular connector that is optionally able to be fixed in the assembly housing, for example an M8, M12 or M23 circular connector. The invention is particularly advantageously suitable for use with circular connectors, but is not intended to be limited to this geometry.

In the context of the invention, the electrical assembly may be any desired electrical assembly that is configured for any desired purpose. However, the electrical assembly may particularly advantageously be a sensor assembly, for example a sensor signal processing means for a sensor integrated in the electrical assembly or a separate sensor (for example an ultrasonic sensor).

The invention also relates to a method for installing an electrical assembly, having at least the following method steps:
providing an assembly housing and an electrical circuit arrangement received in the assembly housing;
providing an electrical connector that has a connecting interface for connection to the electrical circuit arrangement; and
passing the electrical connector through an installation feedthrough of the assembly housing until the connecting interface is electrically and mechanically connected to a corresponding connection region of the electrical circuit arrangement.

According to the invention, provision is made, for the method, for the connecting interface of the electrical connector and the connection region of the electrical circuit arrangement to make contact in a force-fitting manner in the installed state.

It is therefore advantageously possible in particular to dispense with a soldering process in the course of the installation, which may significantly reduce the outlay for the installer and the susceptibility to errors in the course of final installation.

The invention furthermore also relates to an electrical connector for an electrical assembly, which electrical connector has a connecting interface that is able to be electrically and mechanically connected to a corresponding connection region of an electrical circuit arrangement of the electrical assembly, wherein the electrical connector is able to be passed through an installation feedthrough of an assembly housing of the electrical assembly. The electrical connector is characterized in that the connecting interface is able to make contact with the connection region of the electrical circuit arrangement in a force-fitting manner and/or contact is able to be made with the connecting interface by the connection region of the electrical circuit arrangement in a force-fitting manner. The electrical connector may be claimed separately from the electrical assembly disclosed herein. Likewise, the assembly housing and/or the electrical circuit arrangement may be claimed separately.

Features that have been described in connection with one of the subjects of the invention, which are specifically in particular the electrical assembly according to the invention, the electrical connector or the method according to the invention, may also be advantageously applied to the other subjects of the invention. Likewise, advantages specified in connection with one of the subjects of the invention can also be understood in relation to the other subjects of the invention.

In addition, it should be noted that terms such as “comprising”, “having” or “with” do not exclude other features or steps. Furthermore, terms such as “a/an” or “the” indicating steps or features in the singular do not exclude a plurality of features or steps- and vice versa.

It should be mentioned that labels such as “first” or “second”, etc. are used predominantly for the sake of distinguishability between respective device or method features, and are not necessarily intended to indicate that features are mutually dependent or related to one another.

Furthermore, it should be emphasized that the values and parameters described in the present case also encompass deviations or fluctuations of ±10% or less, preferably ±5% or less, more preferably ±1% or less, and very particularly preferably +0.1% or less, of the respectively stated value or parameter, provided that these deviations are not excluded in practice when implementing the invention. The specification of ranges by way of start and end values also encompasses all values and fractions encompassed by the respectively stated range, in particular the start and end values and a respective mean value.

Exemplary embodiments of the invention will be described in more detail below with reference to the drawings.

### DRAWINGS

The figures each show preferred exemplary embodiments in which individual features of the present invention are illustrated in combination with one another. Features of one exemplary embodiment are also able to be implemented separately from the other features of the same exemplary embodiment, and can accordingly be readily combined by a person skilled in the art to form further useful combinations and sub-combinations with features of other exemplary embodiments.

In the figures, functionally identical elements are provided with the same reference signs. In the figures, in each case schematically:

FIG. 1 shows a perspective illustration of an assembly housing and an electrical circuit arrangement, which is preinstalled in the assembly housing, of an electrical assembly according to one exemplary embodiment of the invention;

FIG. 2 shows a perspective illustration of the electrical assembly according to FIG. 1 with an electrical connector installed in the assembly housing and connected to the electrical assembly;

FIG. 3 shows a lateral sectional illustration of the electrical assembly with the in-stalled electrical connector according to FIG. 2;

FIG. 4 shows the electrical connector of FIGS. 2 and 3 in a perspective illustration on its own;

FIG. 5 shows a side view of the electrical connector of FIG. 4;

FIG. 6 shows the electrical connector of FIG. 4 in a front view of the connecting interface;

FIG. 7 shows the electrical connector of FIG. 4 in a lateral sectional illustration along the section line VII-VII of FIG. 6;

FIG. 8 shows a perspective illustration of the electrical connector of FIG. 4 without

FIG. 9 shows the shielding element of the electrical connector of FIG. 4 in a perspective illustration on its own;

FIG. 10 shows a perspective illustration of a single electrical contact element of the electrical connector of FIG. 4; and

FIG. 11 shows a detail enlargement of the electrical circuit arrangement in order to illustrate the connection region.

The figures show, by way of example, an exemplary embodiment of the invention that is not intended to be understood as limiting. The exemplary embodiment will be described below with reference to all the figures.

### DETAILED DESCRIPTION OF THE INVENTION

FIGS. 1 to 3 show, by way of example, an assembly housing 1 and an electrical circuit arrangement 2, which is received in the assembly housing 1, of an electrical assembly 3. By way of example, the electrical circuit arrangement 2 has an electrical printed circuit board 4 on which an electrical circuit 5 is formed. Some electronic components 6 are indicated in FIGS. 1 to 3 by way of example, which may include, inter alia, resistors, coils, capacitors and integrated circuits.

By way of example, the assembly housing 1 is a single-piece, sleeve-shaped, metallic component. Optionally, suitable cover elements may be provided (not illustrated) in order to preferably completely enclose the electrical circuit arrangement 2. Said cover elements may optionally also be electrical display and/or input devices.

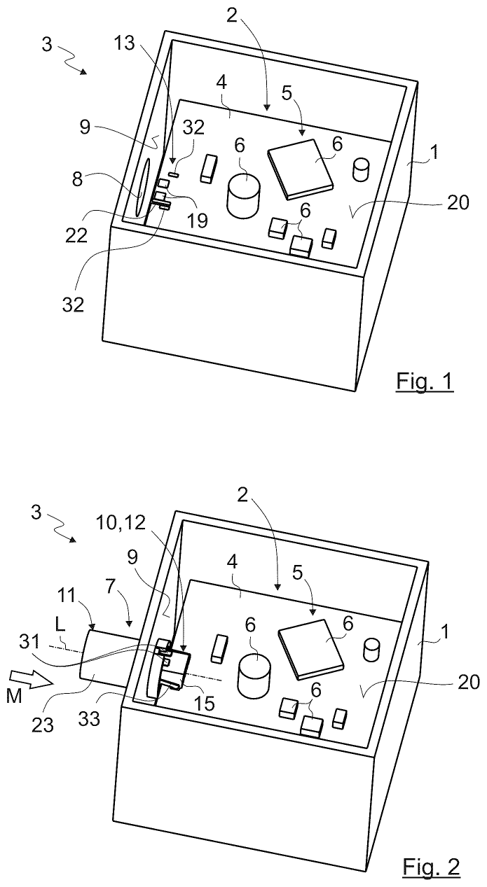

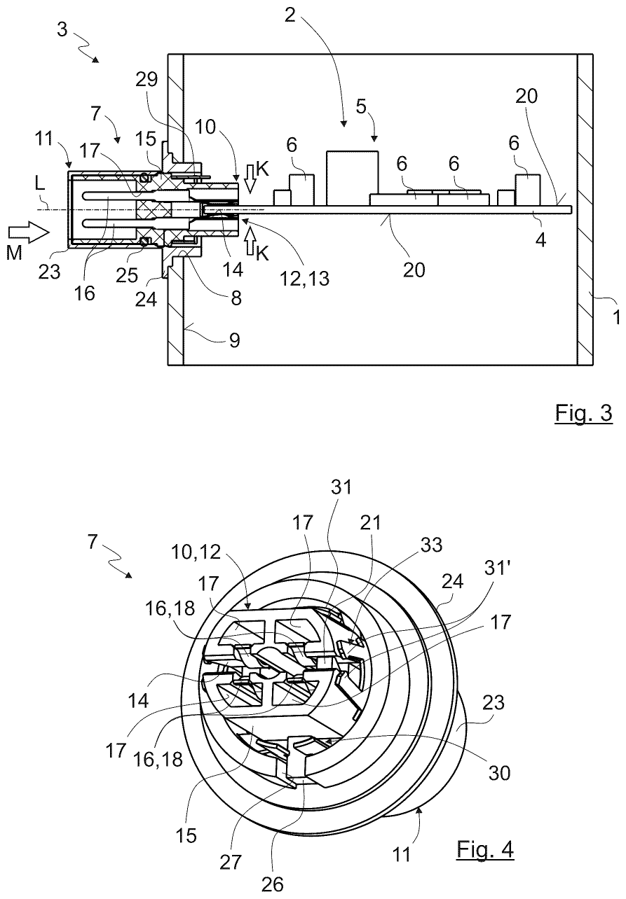

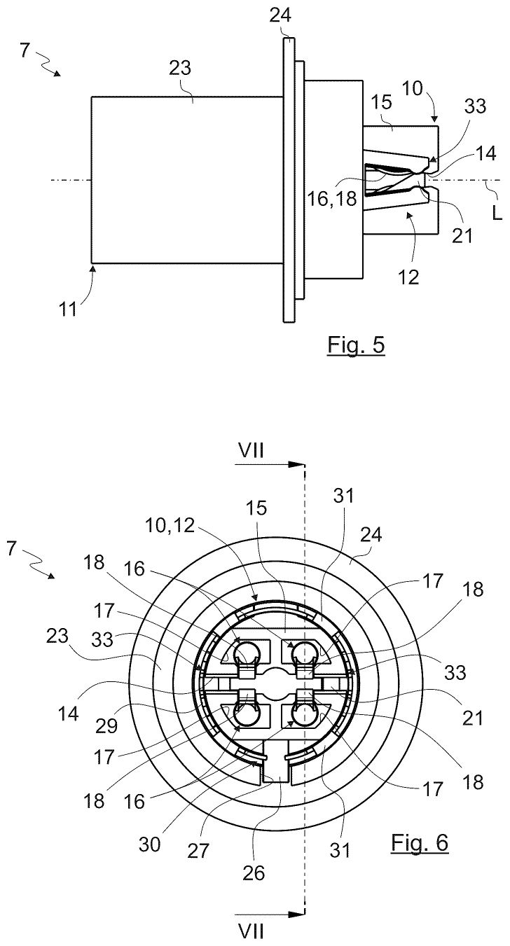

The electrical circuit arrangement 2 is received and fixed within the assembly housing 1. In particular, in the context of a method for installing the electrical assembly 3, provision may be made for the electrical circuit arrangement 2, that is to say in particular the electrical printed circuit board 4 with the electrical circuit 5 formed thereon, to be already preinstalled in the assembly housing 1, as illustrated in FIG. 1. In the context of further installation, provision may then be made for an electrical connector 7 to be passed through an installation feedthrough 8 of the assembly housing 1 up to a final installed state (see FIGS. 2 and 3). The electrical connector 7 is shown in FIGS. 4 to 7 in different views in a respective illustration on its own.

The installation feedthrough 8 of the assembly housing 1 is preferably formed in the manner of a window in a closed side surface 9 of the assembly housing 1. In the exemplary embodiment, the installation feedthrough 8 is a stepped, round bore (however, the profile of the installation feedthrough 8 through the assembly housing 1 may also be smooth). The electrical connector 7 and the installation feedthrough 8 of the assembly housing 1 are designed in such a way that the electrical connector 7 is able to be inserted, along an installation direction M (see FIG. 2), by way of a connecting-interface-side end 10, into the installation feedthrough 8 until it reaches the final installed state, completely from outside the assembly housing 1. In the final installed state, the electrical connector 7 is connected to the electrical circuit arrangement 2, as will be described in more detail below.

In the exemplary embodiment, the electrical connector 7 furthermore has a connection-side end 11, which is averted from the connecting-interface-side end 10, and provides a connection option, which is not illustrated in more detail, for a mating plug-in connector. This is preferably a plug-in interface, which is accessible from outside the assembly housing 1 (which therefore protrudes outwards from the installation feedthrough 8, as illustrated). As already mentioned above, however, the connection-side end 11 of the electrical connector 7 may also form a direct connection option for a cable, such that, for example, a cable is directly connected to the electrical connector 7 and is able to be installed in the assembly housing 1 together with the electrical connector 7.

It should be emphasized that the electrical connector 7 does not necessarily have to protrude out of the installation feedthrough 8 by way of its connection-side end 11, although this may generally be advantageous.

The electrical connector 7 may be fixed to the assembly housing 1, in particular be fixed so as to prevent twisting. For this purpose, the electrical connector 7 may be fixed in particular cohesively to the assembly housing 1, for example by way of a welded connection, soldered connection or adhesively bonded connection. A press-fit or other force-fitting connection and/or a form-fitting connection may also be provided (not illustrated).

By way of example, the electrical connector 7 is illustrated as a circular connector, which represents a particularly advantageous application for the invention, but is not intended to be understood as limiting.

The electrical connector 7 has a connecting interface 12 in the region of the connecting-interface-side end 10, which is electrically and mechanically connected to a corresponding connection region 13 of the electrical circuit arrangement 2 when the electrical connector 7 is in its final installed state. Contact is made between the connecting interface 12 of the electrical connector 7 and the connection region 13 of the electrical circuit arrangement 2 in a force-fitting manner and it is explained in detail below.

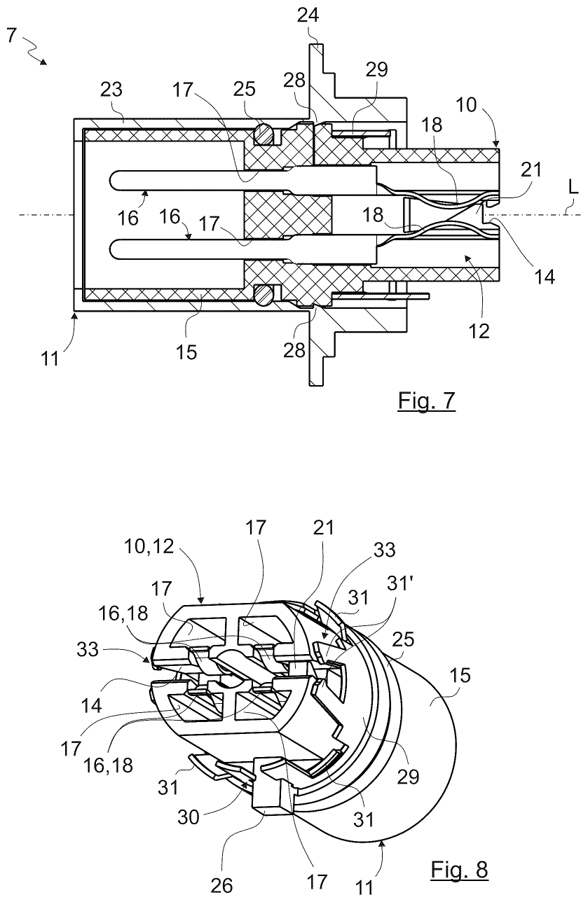

As is apparent in particular with regard to FIG. 3, the connecting interface 12 of the electrical connector 7 and the connection region 13 of the electrical circuit arrangement 2 make contact laterally with respect to the longitudinal axis L or the installation direction M of the electrical connector 7. The contacting direction K or a force vector of the contacting is indicated in FIG. 3 and oriented orthogonally to the installation direction M of the electrical connector 7. For the contacting, the connection region 13 of the electrical circuit arrangement 2 is received in the connecting interface 12. The electrical connector 7 has a receiving slot 14 for the electrical printed circuit board 4 (see in particular FIGS. 7 and 8). The receiving slot 14 is formed in a contact element carrier 15 of the electrical connector 7, in which the individual electrical contact elements 16 of the electrical connector 7 are received in respective contact receptacles 17 or contact chambers. At the connecting-interface-side end 10 of the electrical connector 7, the contact elements 16 are in the form of respective contact spring tabs 18, which project into the connecting interface 12 (see in particular FIGS. 6, 7 and 10). In contrast, at the connection-side end 11 of the electrical connector 7, the contact elements 16 are designed to make contact directly with mating contact elements (which are not illustrated) of a mating plug-in connector (in the exemplary embodiment, the contact elements 16 each form a contact pin).

The contact spring tabs 18 of the contact elements 16 make contact with associated contact points 19 of the connection region 13, which, for example, are able to be seen in FIG. 1 and are illustrated in an enlarged detail in FIG. 11. By way of example, the contact points 19 are contact surfaces or contact pads or conductor paths of the electrical printed circuit board 4.

In the illustrated exemplary embodiment, the connection region 13 of the electrical circuit arrangement 2 is distributed over the two opposite main surfaces 20 of the electrical printed circuit board 4 in order to increase the contact density. By way of example, two contact elements 16 are provided for each main surface 20 of the printed circuit board 4.

At this point it should be mentioned that further variants of elastic contact elements 16 may also be provided as an alternative to the illustrated contact spring tabs 18. By way of example, contact clamps may also be provided such that a single contact element 16 engages around the printed circuit board 4, for example. Spring contact pins may also be provided. Provision may also be made for the elasticity for the lateral contacting to be alternatively or additionally provided by the electrical printed circuit board 4.

The electrical connector 7 and the electrical circuit arrangement 2 form a mutual mechanical coding in order to form a defined mutual orientation and/or a twist prevention means. For this purpose, the contact element carrier 15 has a mechanical coding means 21 in the form of a protrusion, which, due to the off-centered arrangement, is able to engage into a corresponding mechanical mating coding means 22 only when the electrical connector 7 is oriented correctly relative to the electrical printed circuit board 4 (see the longitudinal slot that is oriented in the installation direction M and is able to be seen in FIG. 11). Otherwise, it is not possible to plug the electrical connector 7 onto the electrical printed circuit board 4 completely.

The electrical connector 7 furthermore has an outer conductor contact element 23, which at the same time forms an outer housing for the electrical connector 7 (see in particular FIGS. 4 to 6). The outer conductor contact element 23 has a flange portion 24 with which it is able to support itself on the outside of the assembly housing 1. The outer conductor contact element 23 is also formed in a complementary manner to the installation feedthrough 8 so as to allow the electrical connector 7 to be inserted into the installation feedthrough 8 with an accurate fit. A sealing element, such as the sealing ring 25 that is able to be seen in FIGS. 7 and 8, for example, is optionally able to be arranged between the outer conductor contact element 23 and the contact element carrier 15.

A twist prevention means may also preferably be provided between the contact element carrier 15 and the outer conductor contact element 23. For this purpose, the contact element carrier 15 has, for example, an installation pin 26 and the outer conductor contact element 23 an installation receptacle 27, as can be clearly seen in FIGS. 4 and 6.

The fixing between the outer conductor contact element 23 and the contact element carrier 15 may be effected in a form-fitting, force-fitting and/or cohesive manner. By way of example, the outer conductor contact element 23 may have claws 28 on the inner casing side so as to be gripped in the contact element carrier 15 (see FIG. 7).

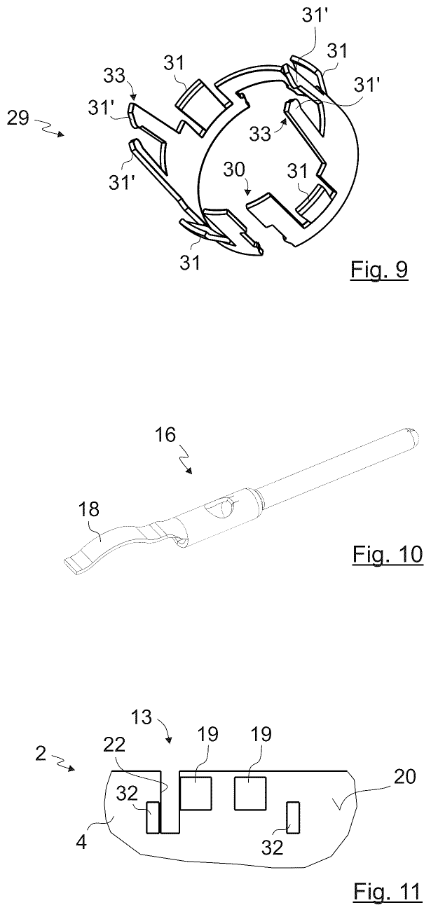

For an outer conductor attachment between the electrical connector 7 and the electrical circuit arrangement 2, the electrical connector 7 has, according to the illustrated exemplary embodiment, a shielding element 29, which is arranged between the outer conductor contact element 23 and the contact element carrier 15. So as to be able to better illustrate this, the outer conductor contact element 23 of the electrical connector 7 is hidden in FIG. 8 and the shielding element 29 is also shown in FIG. 9 in an illustration on its own.

By way of example, the shielding element 29 is a contact plate formed so as to be sleeve-shaped, which is latched on the contact element carrier 15. For this purpose, the shielding element 29 has a latching section 30 (see FIG. 9), which enters into a radial and axial fixing with the already present installation pin 26 of the contact element carrier 15.

For the electrical connection to the outer conductor contact element 23, the shielding element 29 has a group of first contact tabs 31, which are arranged in a manner distributed along the outer circumference, wherein, in principle, even just a single contact tab 31 may be sufficient for the contacting. Electrical contact is made with the electrical printed circuit board 4 or the associated outer conductor contact surfaces 32 (see in particular FIG. 11) via two contact clamps 33, which laterally surround the receiving slot 14 of the electrical connector 7. The contact clamps 33 are each formed from two mutually opposite second contact tabs 31′, wherein, in principle, even just a single second contact tab 31′ may be sufficient for making contact with the electrical printed circuit board 4.

It should be mentioned that the shielding element 29 may possibly also be completely dispensed with, for example if the outer conductor contact element 23 itself forms a direct contacting option for the electrical circuit arrangement 2.

1. An electrical assembly comprising,
an assembly housing,
at least one electrical circuit arrangement located in the assembly housing; and
an electrical connector, which includes a connecting interface that is electrically and mechanically connected to a corresponding connection region of the electrical circuit arrangement,
wherein the electrical connector passes through an installation feedthrough of the assembly housing, and
wherein the connecting interface of the electrical connector and the connection region of the electrical circuit arrangement contact each other in a force-fitting manner.

2. The electrical assembly of claim 1,
wherein the connecting interface of the electrical connector and the connection region of the electrical circuit arrangement contact each other laterally.

3. The electrical assembly of claim 1,
wherein the connection region of the electrical circuit arrangement is received in the connecting interface at least partially, and
wherein the connection region is arranged in a receiving slot of the electrical connector.

4. The electrical assembly of claim 1,
wherein the connection region of the electrical circuit arrangement is distributed over two opposite main surfaces of the electrical circuit arrangement, and
wherein the connecting interface contacts the connection region via each of said main surfaces.

5. The electrical assembly of claim 1,
wherein the connecting interface includes at least one contact spring tab, and
wherein the at least one contact spring tab contacts an associated contact point of the connection region.

6. The electrical assembly of claim 1,
wherein the assembly housing is a single-piece, metallic component.

7. The electrical assembly of claim 1,
wherein the installation feedthrough is formed as a window in a closed side surface of the assembly housing.

8. The electrical assembly of claim 1,
wherein the electrical connector is fixed to the assembly housing in a way that prevents twisting.

9. The electrical assembly of claim 1,
wherein the electrical connector and the installation feedthrough of the assembly housing are designed in such a way that the electrical connector is insertable, by way of a connecting-interface-side end, from outside the assembly housing into the installation feedthrough until the electrical connector reaches a final installed state in which the connecting interface is connected to the electrical circuit arrangement.

10. The electrical assembly of claim 1,
wherein the electrical connector and the electrical circuit arrangement form a mutual mechanical coding that provides at least one of (a) to specifies a defined mutual orientation and (b) prevents twisting.

11. The electrical assembly of claim 1,
wherein the electrical connector further includes an outer conductor contact element and a contact element carrier located in the outer conductor contact element.

12. The electrical assembly of claim 11,
wherein the electrical connector further includes a shielding element that is connected to the outer conductor contact element via at least one first contact tab and to the electrical circuit arrangement via at least one second contact tab.

13. The electrical assembly of claim 1,
wherein the electrical circuit arrangement includes a carrier plate and an electrical circuit formed on the carrier plate.

14. The electrical assembly of claim 1,
wherein the electrical connector further includes at least one contact element that ex-tends in a single piece along a longitudinal extent of the electrical connector up to the connecting interface and that directly contacts the electrical circuit arrangement in the connection region.

15. A method for installing an electrical assembly, the method comprising:
providing an assembly housing and an electrical circuit arrangement located in the assembly housing;
providing an electrical connector that includes a connecting interface; and
passing the electrical connector through an installation feedthrough of the assembly housing until the connecting interface is electrically and mechanically connected to a corresponding connection region of the electrical circuit arrangement,
such that the connecting interface of the electrical connector and the connection region of the electrical circuit arrangement contact each other in a force-fitting manner in an installed state.

16. The method of claim 15,
wherein the connecting interface of the electrical connector and the connection region of the electrical circuit arrangement contact each other laterally.

17. The method of claim 15,
wherein the connection region of the electrical circuit arrangement is received in the connecting interface at least partially, and
wherein the connection region is arranged in a receiving slot of the electrical connector.

18. The method of claim 15,
wherein the connection region of the electrical circuit arrangement is distributed over two opposite main surfaces of the electrical circuit arrangement, and
wherein the connecting interface contacts the connection region via each of said main surfaces.

19. The method of claim 15,
wherein the connecting interface includes at least one contact spring tab, and
wherein the at least one contact spring tab contacts an associated contact point of the connection region.

20. The method of claim 15,
wherein the assembly housing is a single-piece, metallic component.
